(19) United States
(12) Patent Application Publication
(10) Pub. No.: US 2006/0197092 A1
(43) Pub. Date: Sep. 7, 2006

(54) System and method for forming conductive material on a substrate

(76) Inventors: Randy Hoffman, Corvallis, OR (US); Gregory Herman, Albany, OR (US); Curt Lee Nelson, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/158,432

(22) Filed: Jun. 22, 2005

Related U.S. Application Data
(63) Continuation-in-part of application No. 11/072,947, filed on Mar. 3, 2005.

(51) Int. Cl. H01L 29/04

(52) U.S. Cl. 257/72

(57) ABSTRACT

A method for forming a conductive material on a substrate includes laser annealing a selected portion of a blanket coated material to form a conductive region.

### RELATED APPLICATIONS

The present application is a continuation-in-part of application entitled, “Thin-Film Device,” U.S. Ser. No. 11/072,947, filed on Mar. 3, 2005, which application is incorporated by reference herein in its entirety.

### BACKGROUND

Electronic devices, such as integrated circuits, solar cells, or electronic displays, for example, may be comprised of one or more electrical devices, such as one or more thin-film transistors (TFTs). Methods or materials utilized to form electrical devices such as these may vary, and one or more of these methods or materials may have particular disadvantages. For example, use of such methods or materials may be time-consuming or expensive, may involve the use of high temperature processing, or may not produce devices having the desired characteristics.

### SUMMARY

An exemplary method for forming a conductive material on a substrate includes laser annealing a selected portion of a blanket coated material to form a conductive region.

In another exemplary embodiment, a thin-film device includes a conductive region formed by laser annealing a selected portion of a blanket coated material.

### BRIEF DESCRIPTION OF THE DRAWINGS

The accompanying drawings illustrate various embodiments of the present system and method and are a part of the specification. The illustrated embodiments are merely examples of the present system and method and do not limit the scope thereof.

FIGS. 1A and 1B illustrate various embodiments of a semiconductor device, such as a thin-film transistor.

FIG. 2 illustrates a side cross-sectional view of a semiconductor device, according to one exemplary embodiment.

FIG. 3 illustrates a simplified top-view of the exemplary semiconductor device of FIG. 2, according to one exemplary embodiment.

FIG. 4 illustrates a cross-sectional side view of a transistor array, according to various exemplary embodiments.

FIG. 5 is a flow chart illustrating a method for selectively forming conductive elements on a substrate, according to one exemplary embodiment.

FIG. 6 is a flow chart illustrating a method for forming an active matrix backplane, according to one exemplary embodiment.

FIG. 7 is a perspective view illustrating the formation of a number of conductive elements on a substrate, according to one exemplary embodiment.

FIG. 8 is a perspective view illustrating the formation of a gate dielectric on the substrate of FIG. 7, according to one exemplary embodiment.

FIG. 9 is a perspective view illustrating the formation of additional conductive and semiconductive elements on the substrate of FIGS. 7 and 8, according to one exemplary embodiment.

Throughout the drawings, identical reference numbers designate similar, but not necessarily identical, elements.

### DETAILED DESCRIPTION

An exemplary system and method for forming conductive material on a desired substrate are disclosed herein. Specifically, exemplary methods for selectively annealing an oxide film to form conductive elements on a desired substrate are described in detail. According to one exemplary method, an oxide layer is selectively annealed via a laser process to form desired conductive elements. Embodiments and examples of the present exemplary systems and methods will be described in detail below.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present disclosure.

Additionally, as used herein, and in the appended claims, the term “semiconductor”, “semiconducting”, or “semiconductive” shall be understood to mean any material whose conductivity can be modulated (such as by doping the material, or by application of an external electric field, such as in a field-effect transistor structure) across a relatively broad range, typically several orders of magnitude. Consequently, as used herein, a “good” or “useful” semiconductor is a material with high carrier mobility, low defect (trap) density, and relatively low carrier concentration without the presence of external influence, such as thin-film transistor (TFT) gate voltage. A relatively low carrier concentration, in this context, implies a carrier concentration substantially lower than that of a typical metallic conductor, for which a typical carrier concentration is about 10²¹ carriers per cubic centimeter. More specifically, in order to function acceptably as a TFT channel material, a carrier concentration below about 10¹⁸ carriers per cubic centimeter is desired.

As used herein, the terms “conductor”, “conducting”, or “conductive” are meant to be understood as any material which offers low resistance or opposition to the flow of electric current due to high mobility and high carrier concentration.

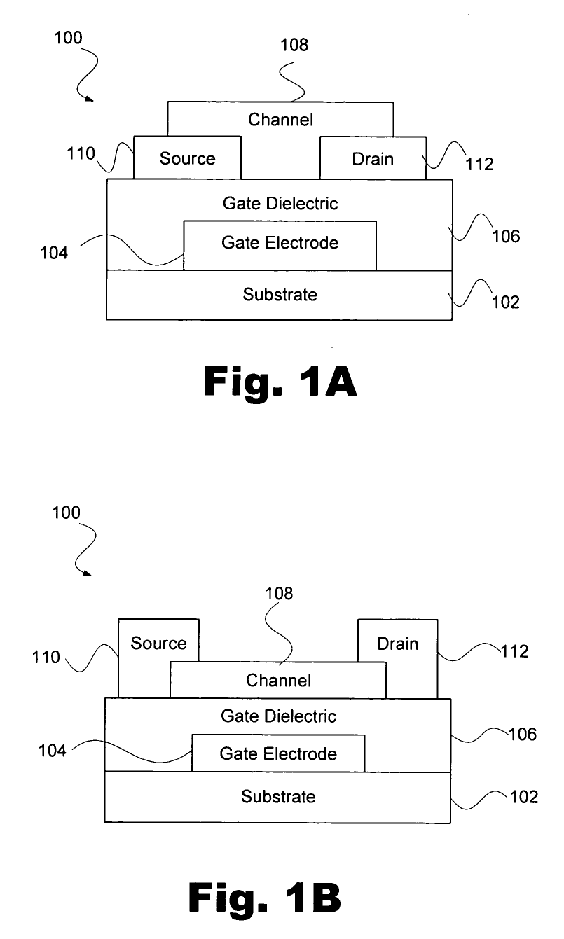

It should also be understood that various semiconductor devices such as transistor structures may be employed in connection with the various embodiments of the present exemplary systems and methods. For example, the present systems and methods may be incorporated to form any number of semiconductor structures, field effect transistors including thin-film transistors (TFTs), active matrix displays, logic inverters, amplifiers, and the like. As illustrated in FIGS. 1A-1B, exemplary thin-film transistor embodiments may be formed with the present systems and methods. The thin-film transistors can be of any type including, but not limited to, horizontal, vertical, coplanar electrode, staggered electrode, top-gate, bottom-gate, single-gate, and double-gate transistors, just to name a few.

In the following description, for purposes of explanation, numerous specific details are set forth in order to provide a thorough understanding of the present system and method for forming conductive material on a desired substrate. It will be apparent, however, to one skilled in the art, that the present method may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

Electronic devices, such as semiconductor devices, display devices, nanotechnology devices, conductive devices, and dielectric devices, for example, may comprise one or more electronic components. The one or more electronic components may comprise one or more thin-film components, which may be comprised of one or more thin films. As used in the present specification and the appended claims, the term “or” means a sentential connective that forms a complex sentence which is true when one or more of its constituent sentences is true. Additionally, as used herein, the term “thin film” refers to a layer of one or more materials formed to a thickness, such that surface properties of the one or more materials may be observed, and these properties may vary from bulk material properties. Thin films may additionally be referred to as component layers, and one or more component layers may comprise one or more layers of material, which may be referred to as material layers, for example. The one or more material or component layers may have electrical or chemical properties, such as conductivity, chemical interface properties, charge flow, or processability. The one or more material or component layers may additionally be patterned, for example.

The one or more material or component layers, in combination with one or more other material or component layers may form one or more electrical components, such as thin-film transistors (TFTs), capacitors, diodes, resistors, photovoltaic cells, insulators, conductors, optically active components, or the like. Components such as TFTs, in particular, may, for example, be utilized in components including smart packages and display components including, for example, radio frequency identification (RFID) tags and electroluminescent and liquid crystal displays (LCD), such as active matrix liquid crystal display (AMLCD) devices, for example.

At least as part of the fabrication process of electronic components, such as thin-film transistors, one or more layers of material may be formed at least as part of one or more of the component layers, such as by forming at least a portion of an electrode, including: source, drain, or gate electrodes; a channel layer; and/or a dielectric layer. These one or more layers of material may be formed on or over a substrate, for example.

In at least one exemplary embodiment, one or more processes utilized may include one or more low temperature processes. As used herein, low temperature processes or processing refers to one or more processes that may be performed at relatively low temperatures as compared to one or more other processes. For example, processes that may be utilized to form material layers of a TFT, may be performed at particular temperatures, such as temperatures equal to or less than approximately 300 degrees Celsius, including processes performed at temperatures equal to or less than approximately 100 degrees Celsius. It should be noted that particular temperature ranges may depend, in part, on the type of materials or processes utilized, and claimed subject matter is not limited in this respect. In at least one exemplary embodiment, utilization of low temperature processes may provide the capability to utilize materials that would not be suitable for use in non-low temperature processes, for example. Additionally, use of low temperature materials or processes may result in the formation of a component, such as a TFT, having improved mechanical flexibility or resistance to mechanical failure such as by delamination or cracking, as compared to components formed by use of non-low temperature processes, and may additionally result in the formation of a device having other properties, as will be explained in further detail later. However, it is worthwhile to note that claimed subject matter is not limited in this respect.

One or more processes or materials, such as low temperature processes or materials may be utilized to form one or more material or component layers of a component. For example, one or more temperature sensitive materials, such as temperature sensitive substrate materials, channel layer materials or dielectric layer materials may be utilized, and this may include materials that may have characteristics such as flexibility, for example, or may include materials not suitable for use in non-low temperature processes. Additionally, according to various exemplary embodiments, one or more low temperature processes, such as selective laser annealing; sputter deposition processes including RF (radio frequency) sputtering, DC sputtering, DC-pulsed sputtering, or reactive sputtering, wherein the substrate may be unheated or maintained at a suitably low temperature; atomic layer deposition (ALD); evaporation processes, including thermal or electron-beam evaporation; or roll-coating, gravure-coating, spin-coating, dip-coating, or spray-coating, for example, may be utilized in at least one embodiment.

Furthermore, electrical components, such as TFTs, for example, may be at least partially formed by laser annealing or processing. As used in the present specification, and the appended claims, the term “laser annealing” refers to locally exposing a selected portion of a suitable material to one or more laser beams to alter at least one or more properties of the suitable material. Laser annealing in the present exemplary system and method, as opposed to thermal annealing of the entire substrate, may obviate the need for subtractive processing or selective removal, such as by photolithography and the like, of portions of the suitable material that may otherwise hinder device to device electrical isolation for adjacent thin-film transistors or other electrical components. In addition, laser annealing may, under some circumstances, be performed at lower temperatures than thermal annealing, which may allow use of heat sensitive substrates that may otherwise be damaged by thermal annealing. Furthermore, laser annealing may allow thermal treatment to higher temperatures than may be appropriate for use with heat sensitive substrates under other circumstances due to the controlled thermal transient from the laser, the localized nature of the laser spot, or the thermal conduction pathways from the localized laser spot, for example. Additionally, other means can be utilized to locally modify one or more material properties, including high density infrared plasma arc light, electron beam exposure, ion beam exposure, and the like. It should of course be noted that the present exemplary system and method is not limited in this regard.

### Exemplary Structure

FIGS. 1A and 1B illustrate exemplary embodiments of bottom-gate transistors that may include laser annealed active regions formed by the present exemplary systems and methods. According to various embodiments, the thin-film transistor (100) can form a portion of any number of devices including, but in no way limited to, an active matrix display device, such as an active matrix liquid crystal display (AMLCD) device; an active matrix detection device, such as an active matrix x-ray detector device; a logic gate, such as a logic inverter; and/or an analog circuit, such as an amplifier. The thin-film transistor (100) can also be included in an infrared device where transparent components are used.

While FIGS. 1A and 1B illustrate only a few bottom-gate transistors, the present exemplary systems and methods may be used to form any number of semiconductor apparatuses in various configurations. As shown in FIGS. 1A and 1B, the exemplary transistors (100) include a substrate (102), a gate electrode (104), a gate dielectric (106), a channel (108), a source electrode (110), and a drain electrode (112). Further, in each of the bottom-gate transistors, the gate dielectric (106) is positioned between the gate electrode (104) and the source and drain electrodes (110, 112) such that the gate dielectric (106) physically separates the gate electrode (104) from the source and the drain electrodes (110, 112). Additionally, in each of the exemplary bottom-gate transistors, the source and the drain electrodes (110, 112) are separately positioned, thereby forming a region between the source and drain electrodes (110, 112) for interposing the channel (108). Consequently, the gate dielectric (106) is positioned adjacent the channel (108) and physically separates the source and drain electrodes (110, 112) from the gate electrode (104). Further, the channel (108) is positioned adjacent the gate dielectric (106) and is interposed between the source and drain electrodes (110, 112).

In each of FIGS. 1A and 1B, the channel (108) interposed between the source and the drain electrodes (110, 112) may be made of a semiconducting material such as zinc oxide to provide a controllable electric pathway configured to selectively facilitate a movement of an electrical charge between the source and drain electrodes (110, 112) via the channel (108). According to the present exemplary systems and methods, the source and the drain electrodes (110, 112), the semiconducting channel (108), and a number of additional conducting and/or semiconducting components may include laser annealed regions. In this context, laser annealed regions may be formed by selectively exposing a region of a material, such as an oxide material, to one or more laser beams or laser pulses. The oxide material may comprise any of a number of suitable materials such as zinc oxide, tin oxide, indium oxide, cadmium oxide, gallium oxide, or combinations thereof, including zinc tin oxide, zinc indium oxide, or combinations thereof, to name but a few examples.

With regards to FIGS. 1A and 1B, the substrate (102) may comprise one or more types of plastic or one or more organic substrate materials, such as polyimides (PI), including Kapton®; polyethylene terephthalates (PET); polyethersulfones (PES); polyetherimides (PEI); polycarbonates (PC); polyethylenenaphthalates (PEN); acrylics, including acrylates and methacrylates, such as polymethylmethacrylates (PMMA); or combinations thereof, but claimed subject matter is not so limited. Additionally, according to one exemplary embodiment, the substrate (102) may also comprise one or more inorganic materials, including silicon, silicon dioxide, one or more types of glass, quartz, sapphire, stainless steel and metal foils, including foils of aluminum or copper, or a variety of other suitable materials. Further, in at least one exemplary embodiment, wherein a substrate material is substantially comprised of one or more metals, an insulator layer may be utilized in addition to the one or more metals to form the substrate. A choice of substrate materials may determine certain characteristics or tolerances that may influence the available semiconductor fabrication processes that are suitable for use with a particular substrate material. For example, organic substrate materials may be more sensitive to heat and as such may be more suitable for use with lower temperature processes than those that may be suitable for use with inorganic substrates under certain circumstances. Choice of substrate material may depend on a variety of factors including, but in no way limited to, heat sensitivity, cost, flexibility, durability, resistance to failure, surface morphology, chemical stability, optical transparency, barrier properties, etc.

As used herein, the oxide material may comprise various combinations of the above listed oxides with other oxides including, but in no way limited to, lead oxide, germanium oxide, copper oxide, silver oxide, or antimony oxide, to name but a few examples. The formation of the source and the drain electrodes (110, 112), the semiconducting channel (108), and a number of additional conducting and/or semiconducting components will be provided below according to the present exemplary systems and methods.

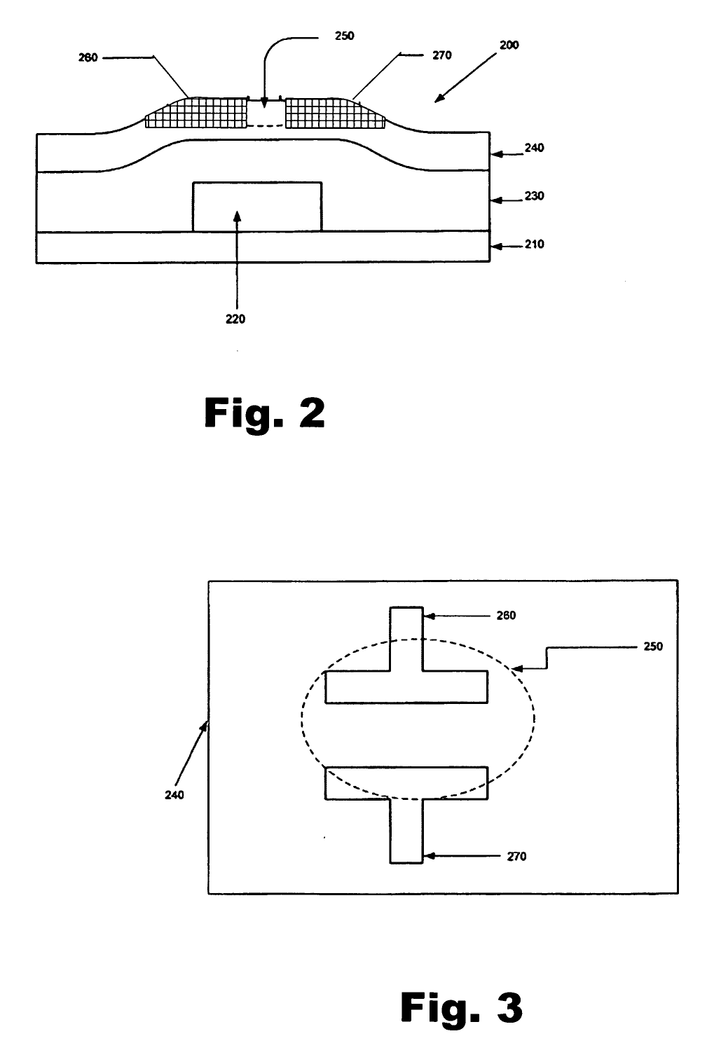

FIG. 2 is a cross-sectional side view of an exemplary embodiment (200), such as thin film transistor that may include the components illustrated above with reference to FIGS. 1A and 1B. With regard to FIG. 2, embodiment (200) may comprise a first layer (210), such as a substrate, for example. Embodiment (200) may further comprise a second layer (220). The second layer (220) may comprise a gate electrode layer, for example. Embodiment (200) may also include a third layer (230), such as a gate dielectric layer which may comprise silicon dioxide or other materials. The present exemplary embodiment (200) may further include an un-patterned oxide layer (240). Un-patterned oxide layer (240) may comprise a blanket coated oxide layer deposited using any number of deposition processes including, but in no way limited to, vacuum deposition processes, spin coating processes, curtain coating processes, inkjet coating processes, and the like. In this context, the term “blanket coated” may refer to any un-patterned deposition such as one that may cover a relatively small portion of a substrate, patterned using a shadow mask for example, up to and including a deposition that may cover a relatively large portion of a substrate, which may under some circumstances include an entire substrate, depending on various factors, for example. In one exemplary embodiment (200), a blanket coated oxide layer may correspond to an actual surface area on the order of centimeters, for example, though the actual surface area of the blanket coated oxide layer may vary widely. In addition, the blanket coated or un-patterned oxide layer may comprise a layer such that, as deposited and without further treatment, the area of the blanket coated or un-patterned oxide layer may be substantially larger than that of a single thin-film transistor or other semiconductor component. As used herein, the un-patterned oxide layer (240) may comprise an oxide material such as zinc oxide, tin oxide, indium oxide, cadmium oxide, gallium oxide, or combinations thereof, including zinc tin oxide, zinc indium oxide, or combinations thereof, to name but a few examples.

FIG. 3 is a depiction of a simplified top view of the exemplary embodiment (200) of FIG. 2. As illustrated in FIG. 3, the present exemplary embodiment (200) may additionally have a source, such as the illustrated source electrode (260), along with a drain, such as the illustrated drain electrode (270). As shown in FIG. 3 there may be a gap between the source electrode (260) and the drain electrode (270). According to one exemplary embodiment, the laser annealed semiconducting active region (250) may be positioned at least partially within the gap between the source electrode (260) and the drain electrode (270). In this context, the semiconducting active region (250) may, in combination with the source electrode (260), the drain electrode (270) and/or other layers or structures, function as a channel region such that the combination may function as a transistor, such as a thin-film transistor, for example.

Though the exemplary embodiment (200) has been described above with regard to a particular structure it should be noted that the thin-film transistors may be of any type or structure, including but not limited to, horizontal, vertical, coplanar electrode, staggered electrode, top-gate, bottom-gate, single-gate, and double-gate, to name but a few. As used herein, a “coplanar electrode configuration” is meant to be understood as any transistor structure where the source and drain electrodes are positioned on the same side of the channel layer as the gate electrode. Further, as used herein, a “staggered electrode configuration” is meant to be understood as any transistor structure where the source and drain electrodes are positioned on the opposite side of the channel layer as the gate electrode.

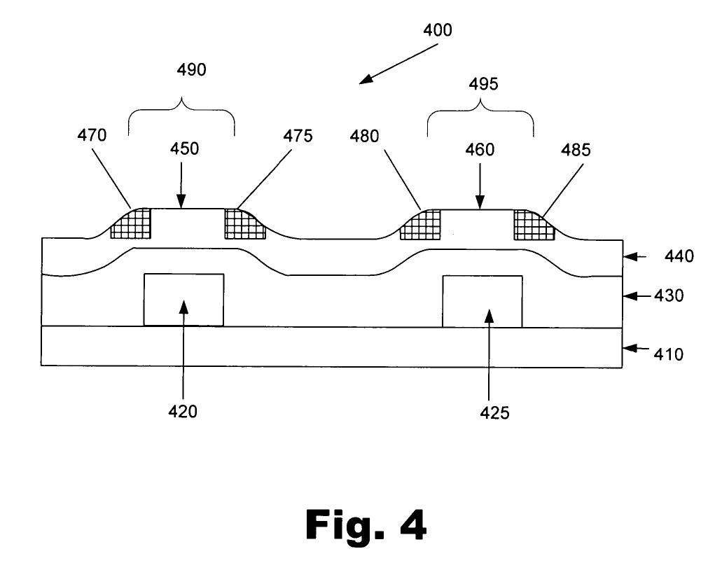

FIG. 4 is a depiction of an exemplary semiconductor device array structure (400). With regard to FIG. 4, the exemplary array structure (400) may include a first layer (410), such as a substrate layer. Similar to the substrate layers previously described, the first layer (410) may include, but is in no way limited to, one or more types of plastic or one or more organic substrate materials such as polyimides (PI), including Kapton; polyethylene terephthalates (PET); polyethersulfones (PES); polyetherimides (PEI); polycarbonates (PC); polyethylenenaphthalates (PEN); acrylics, including acrylates, and methacrylates, such as polymethylmethacrylates (PMMA); or combinations thereof. Alternatively, the first layer (410) may include, but is no way limited to, one or more inorganic materials, including silicon, silicon dioxide, one or more types of glass, stainless steel and metal foils, including foils of aluminum and copper. Additionally, in at least one exemplary embodiment, wherein the first layer (410) includes one or more metals, an insulator layer (not shown) may be utilized in addition to the one or more metals to form a first layer (410).

Further, as illustrated in FIG. 4, the exemplary array structure (400) includes a first gate electrode (420) and a second gate electrode (425). The exemplary array structure (400) may further include a third layer (430), such as a gate insulator layer, which may comprise silicon dioxide or other materials such as inorganic dielectrics such as zirconium oxide, tantalum oxide, yttrium oxide, lanthanum oxide, silicon oxide, aluminum oxide, hafnium oxide, barium zirconate titanate, barium strontium titanate, silicon nitride, or silicon oxynitride, as just a few examples. In addition, the third layer (430) may comprise organic dielectrics such as curable monomers, including UV curable acrylic monomers, UV curable monomers, thermal curable monomers; acrylic polymers; polymer solutions such as melted polymers or oligomer solutions; poly methyl methacrylate, poly vinylphenol; benzocyclobutene; or one or more polyimides, to name but a few examples. According to one exemplary embodiment the third layer (430) may have a thickness that may under some circumstance be in a range of approximately 20 to 1000 nm. Also, the third layer (430) may under some circumstance comprise multiple sub-layers, including one or more inorganic dielectric or organic dielectric layers, though other materials may be used to form a gate insulator layer and will be understood by one of ordinary skill.

Moreover, as illustrated in FIG. 4, the exemplary array structure (400) may further include an un-patterned or blanket coated oxide layer (440), as described previously. According to one exemplary embodiment, the un-patterned oxide layer (440) of the exemplary array structure (400) may further comprise a first selectively annealed semiconductive active region (450) and a second selectively annealed semiconductive active region (460), which may, within the overall structure and in connection with other layers or structures, function as a first channel region and a second channel region for a first transistor and a second transistor of the exemplary array structure, respectively. The first selectively annealed semiconductive active region (450) and the second selectively annealed semiconductive active region (460) may be formed by laser annealing a respective first selected portion and a second selected portion of the un-patterned oxide layer (440), as described in detail below.

The exemplary array structure (400) illustrated in FIG. 4 may further include a first and a second source electrode (470, 480) and a first and a second drain electrode (475, 485). According to the present exemplary systems and methods, the first and second drain electrodes (475, 485) as well as the first and second source electrodes (470, 480) may be formed via selective laser annealing an un-patterned oxide layer (440) above or in-plane with the semiconductive active region (460), for example. The source and drain electrodes may be formed within the same un-patterned oxide layer (440) that includes the semiconductive active regions (450, 460), or may be formed within an adjacent un-patterned layer of suitable oxide material. Although other materials may be used, the first and second source electrodes (470, 480) and the first and second drain electrodes (475, 485) may be formed in an oxide semiconductor material including, but in no way limited to, zinc oxide or zinc tin oxide.

According to one exemplary embodiment, the first gate electrode (420), the first source electrode (470), the first drain electrode (475), the gate insulator layer (430), and the first active region (450) may function as a first transistor (490) of the exemplary array structure (400), such that the first semiconductive active region (450) may function as a first channel region. Likewise, the second gate electrode (425), the second source electrode (480), the second drain electrode (485), the gate insulator layer (430), and the second active region (460) may function as a second transistor (495), such that the second semiconductive active region (460) may function as a second channel region. As illustrated, the exemplary array structure (400) may achieve effective electrical isolation between the first transistor (490) and the second transistor (495) without requiring a subtractive processing of non-annealed portions of un-patterned oxide layer (440), such as by employing a photolithography process or the like, for example. For certain materials, such as zinc oxide, indium oxide, tin oxide, cadmium oxide, gallium oxide, or combinations thereof, including zinc tin oxide, zinc indium oxide, or other combinations thereof, to name but a few examples, and for appropriately selected deposition technique and conditions, the non-annealed portions of the un-patterned oxide layer (440) may exhibit certain properties, such as a relatively large and positive (in the case of n-channel transistor) turn-on voltage, relatively low mobility, relatively low carrier concentration, or relatively high trap density, such that the non-annealed portion of the un-patterned oxide layer may exhibit relatively low conductivity resulting in relatively minimal leakage between adjacent transistor structures (490 and 495). When materials such as those mentioned above or below are used to form an un-patterned oxide layer (440), the properties of the non-annealed material may hinder device to device current leakage between adjacent transistors, such as the first transistor (490) and the second transistor (495). However, as discussed further below, any selectively annealed portion, such as the first semiconductive active region (450) and the second semiconductive active region (460), of the un-patterned oxide layer (440), may, due to having been selectively annealed, have properties such that the selectively annealed portion may function as a part, such as a channel region, of a thin-film transistor, for example.

According to one exemplary embodiment, an un-patterned oxide layer, such as the un-patterned oxide layer (440) illustrated in FIG. 4, when comprising zinc oxide, tin oxide, indium oxide, cadmium oxide, gallium oxide, or combinations thereof, including zinc tin oxide, zinc indium oxide, or other combinations thereof, which may have been RF sputtered onto a gate insulating layer (430), may have properties such as relatively low mobility, relatively high trap density and relatively large, and in the case of an n-channel transistor, positive turn-on voltage such that the un-patterned oxide layer (440) may not effectively pass current laterally between adjacent contacts, such as adjacent transistor sources and drains, for example. However, according to the present exemplary embodiment, the first and second semiconductive active regions (450, 460), having been selectively annealed in a laser treatment process may exhibit much different properties such as a relatively smaller turn-on voltage, a relatively lower trap density, and a relatively higher mobility such that the semiconductive active regions (450, 460) may have suitable properties for functioning as channel regions in the first transistor (490) and the second transistor (495) respectively. Similarly, the first and second source (470, 480) and drain (475, 485) electrodes may exhibit conductive properties suitable for functioning as electrodes. Exemplary systems and methods for forming the above-mentioned thin-film transistor configurations will be described in detail below.

Exemplary Formation

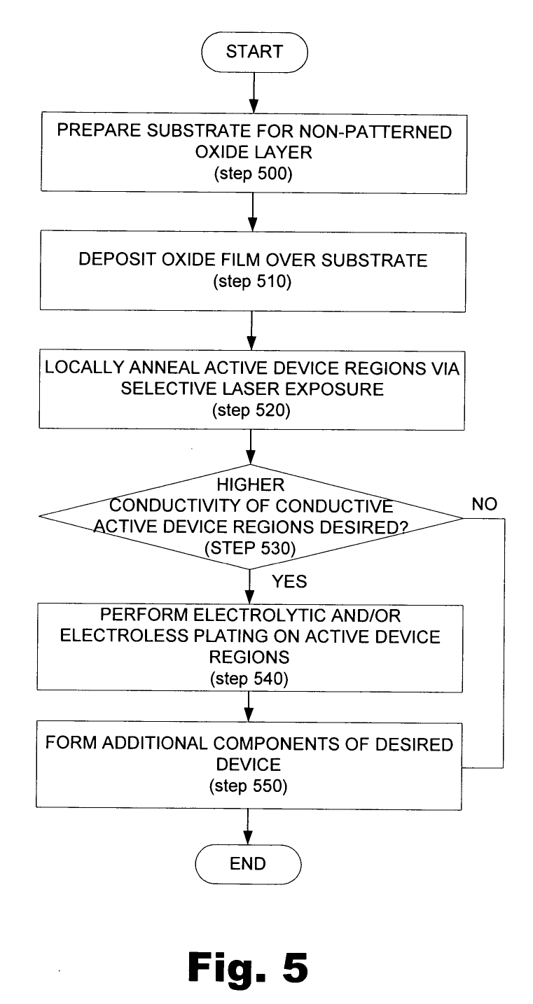

FIG. 5 illustrates an exemplary method for using laser treatments to form conductive areas, such as source and drain electrodes, on a substrate, according to one exemplary embodiment. As illustrated in FIG. 5, the exemplary method begins by first preparing a substrate to receive a non-patterned oxide layer (step 500). Once the substrate is prepared, the non-patterned oxide layer may be formed as a film over the desired substrate (step 510). With the non-patterned oxide layer formed, desired semiconductive device regions and conductive device and circuit regions may be locally annealed via selective laser exposure (step 520). It may then be determined whether a higher conductivity is desired in the conductive regions (step 530). If a higher conductivity of the conductive regions is desired (YES, step 530), electrolytic and/or electroless plating may be performed on the conductive regions to provide additional conductive material (step 540). Once the additional conductive material has been formed, or if no higher conductivity is desired (NO, step 530), any additional components of the desired resulting device and/or circuit may be formed on the substrate (step 550). Further details of each of the above-mentioned steps will be described in further detail below.

As illustrated, the above-mentioned method begins by first preparing the desired substrate to receive a non-patterned oxide layer (step 500). According to one exemplary embodiment, any number of the above-mentioned components may be formed on the desired substrate to form an integrated circuit, prior to the deposition of the non-patterned oxide layer. More specifically, according to one exemplary embodiment, all or part of an active matrix display backplane may be formed on the desired substrate prior to deposition of the non-patterned oxide layer.

Once the substrate has been prepared to receive the non-patterned oxide layer, the non-patterned oxide layer is formed on the desired substrate (step 510). According to one exemplary embodiment, the formation of the non-patterned oxide layer on the desired substrate may be performed by any appropriate deposition processes including, but in no way limited to, a vacuum deposition process. More particularly, appropriate vacuum deposition processes that may be used include, but are in no way limited to, RF (radio frequency) sputtering, DC sputtering, DC-pulsed sputtering, reactive sputtering, thermal evaporation, electron-beam evaporation, chemical vapor deposition (CVD), or atomic layer deposition (ALD). Additionally, according to one exemplary embodiment, it may be useful to form a multi-layer stack, e.g., two or more layers of different oxides, with the multi-layer stack comprising the “non-patterned oxide layer”.

According to one exemplary embodiment, the non-patterned oxide layer may be formed using sputter deposition at a sufficiently low power so as to avoid appreciable substrate heating, thereby maintaining compatibility with low-cost, low-temperature flexible substrate materials; alternatively, active cooling may be employed to maintain a desired substrate temperature. In addition, the deposition of the non-patterned oxide layer may be carried out with a heated or unheated substrate, in an approximately 90% argon and 10% oxygen environment and at a pressure of approximately 5 mTorr, for example.

As mentioned previously, the non-patterned oxide layer may be formed from any number of materials including, but in no way limited to, zinc oxide, tin oxide, indium oxide, cadmium oxide, gallium oxide, or combinations thereof, including zinc tin oxide and zinc indium oxide, to name but a few examples. For example, un-patterned oxide layer 440 may comprise zinc tin oxide with zinc:tin atomic ratio in the range of approximately 1:2 to approximately 1:0.

The as-deposited film has electronic properties such that it cannot effectively pass current laterally between adjacent contacts (e.g., thin-film transistor [TFT] source and drain, active matrix back plane [AMBP] data and control lines, etc.), due to low mobility/high trap density/high turn-on voltage (i.e., high resistivity).

Once the non-patterned oxide layer has been formed on the desired substrate (step 510), the non-patterned oxide layer may be locally annealed in desired active device regions via selective laser exposure to form desired conductive regions and/or semiconductive device regions on the substrate (step 520). According to one exemplary embodiment, film treatment is performed on the non-patterned oxide layer to yield properties, such as electrical conductivity or semiconductivity suitable for desired functions, such as thin-film transistor channel layers, source/drain electrodes and/or circuit interconnects such as active matrix back plane data/control lines. As mentioned previously, these functionalities are traditionally accomplished via standard thermal processing (i.e., annealing), which, if done properly, results in significantly improved conductivity or semiconducting properties. However, if the traditional thermal processing is performed globally to the entire film, (e.g., in a standard thermal annealing process), the device-to-device electrical isolation properties of the as-deposited film are lost, and the film must be physically patterned in order to provide a useful interconnect and/or electrode layer.

According to the present exemplary system and method, acceptable device performance can be obtained while retaining device-to-device electrical isolation, without the use of physical, subtractive patterning. More specifically, by locally “annealing” only the conductive regions and/or semiconductive active device regions via selective laser exposure, desired electrical properties, such as increased conductivity, increased mobility, controlled carrier concentration, and/or reduced defect density may be achieved. According to various embodiments of the present exemplary system and method, localized annealing may be performed by an intense light source such as a laser, by electron bombardment, or by ion bombardment, to locally reduce the resistivity of isolated or interconnected regions that will function as TFT source/drain electrodes, AMBP data/control lines, and/or other electrodes or interconnects. In essence, annealing and patterning steps are combined and accomplished via a single patterned laser treatment step.

According to one exemplary embodiment, the conductive regions and/or semiconducting active device regions of the desired substrate may be selectively annealed via laser exposure (step 520) by selectively exposing the selected portion of un-patterned oxide to at least one or more laser pulses or laser beams. According to one exemplary embodiment, the laser beams or laser pulses of the present system and method may be generated by a UV excimer laser generating laser beams or laser pulses having an approximate range of between 193 and 337 nanometers in wavelength, such as approximately 248 nanometers in wavelength. Alternatively, other lasers having different wavelength ranges may be employed including, but in no way limited to, solid-state visible or near-IR lasers with wavelengths of 355-1064 nanometers, far-IR lasers with wavelengths of 9.6-10.6 um, or fiber lasers with wavelengths of 775-2100 nm, to name but a few examples.

Laser treatment parameters, such as fluence, pulse length, frequency, number of laser pulses, scan speed, duty cycle, etc. may be varied to achieve desired electrical, physical, or chemical properties in the laser annealed regions. Desired properties for semiconducting active regions may comprise a range for transistor turn-on voltage, a range of channel carrier concentration, a range of transistor channel mobility, and a maximum acceptable defect density, for example. Desired properties for conductive regions may comprise a minimum conductivity level, as defined by carrier concentration and carrier mobility. For purposes of illustration only, the UV excimer laser may be employed with a fluence of approximately 5 to 600 millijoules per square centimeter, and a laser pulse count of approximately 10 to 5000, to name but a few possible laser treatment parameters.

According to one exemplary embodiment, the selective annealing of the oxide film via laser treatment includes applying a plurality of laser pulses onto selective areas of the oxide film, making the selective areas oxygen deficient. Since oxygen deficiency is believed responsible for n-type conductivity in many of the oxides listed here, as the resulting oxygen deficiency increases, so too does the carrier concentration, and thus the conductivity, of the affected area of the oxide film. By varying the intensity and/or pulse count of the laser, as well as the ambient in which the laser process takes place, the degree of oxygen deficiency, and consequently the conductivity of the affected portion of the oxide film, may be varied from resistive in nature to conductive.

In another exemplary embodiment, the selective annealing of the oxide film via laser treatment includes applying a plurality of laser pulses onto selective areas of the oxide film, such that the mobility and defect (trap) density of the selective areas are improved while retaining a substantially stoichiometric oxygen concentration; exposure to an appropriate oxidizing ambient during selective annealing may assist in maintaining a substantially stoichiometric oxygen concentration. This improvement in semiconductive properties may be achieved due, in part, to localized heating of the oxide material by the laser, similar to that global film heating in a conventional thermal annealing process. Increased mobility and decreased defect (trap) density may be attributed to improved short-range and/or long-range ordering in the oxide network.

According to the present exemplary system and method, relatively short channel lengths (<5 microns) can be obtained via selective laser annealing due to the precision of the laser patterning of the source/drain, thus leading to higher performance for thin film transistors (as compared to methods yielding larger source/drain gaps). High precision patterning of the data/control lines for the active matrix back plane can be performed. Although the conductivity of such transparent oxide conductors may be lower than that of typical metal interconnects, it is acceptable for use, without additional increase in conductivity, in certain application such as smaller displays for which interconnects are relatively short, thus reducing parasitic series resistances.

After the active device regions have been formed via local annealing (step 520), the user and/or manufacturing apparatus may optionally determine whether a higher conductivity is desired on the conductive active device locations (step 530). As mentioned, the above-mentioned selective annealing may, according to one exemplary embodiment, produce conductive components acceptable for use in smaller displays and the like. However, if larger applications are desired, additional conductivity may be provided. According to one exemplary embodiment, If it is determined that additional conductivity is desired on the conductive locations (YES, step 530), the present exemplary method performs electrolytic and/or electroless plating on the desired active device regions (step 540). For example, when forming backplanes for larger displays, electrolytic and/or electrolysis plating of metallic or other conductive materials may be performed on top of the locally annealed regions to add a metal layer of the desired thickness.

With the local annealing and any additional desired plating performed, the present system and method continue by forming any additional components of the desired device (step 550). According to one exemplary embodiment, a number of the previously mentioned components illustrated in FIGS. 1A through 4 may be formed after formation of the locally annealed regions.

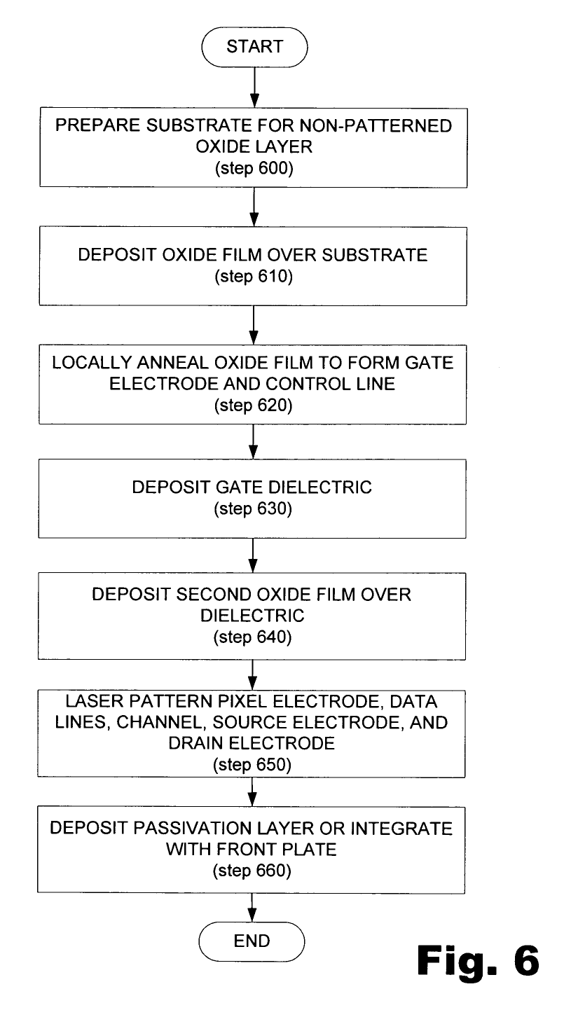

FIGS. 6-9 illustrate an exemplary method for forming an active matrix backplane, according to the present exemplary system and methods. As illustrated in FIG. 6, the exemplary backplane forming method may be performed by first, preparing a substrate to be coated with a non-patterned oxide layer (step 600). As mentioned previously, the preparation of the substrate may include the formation of any number of components desired to form a portion of the resulting configuration.

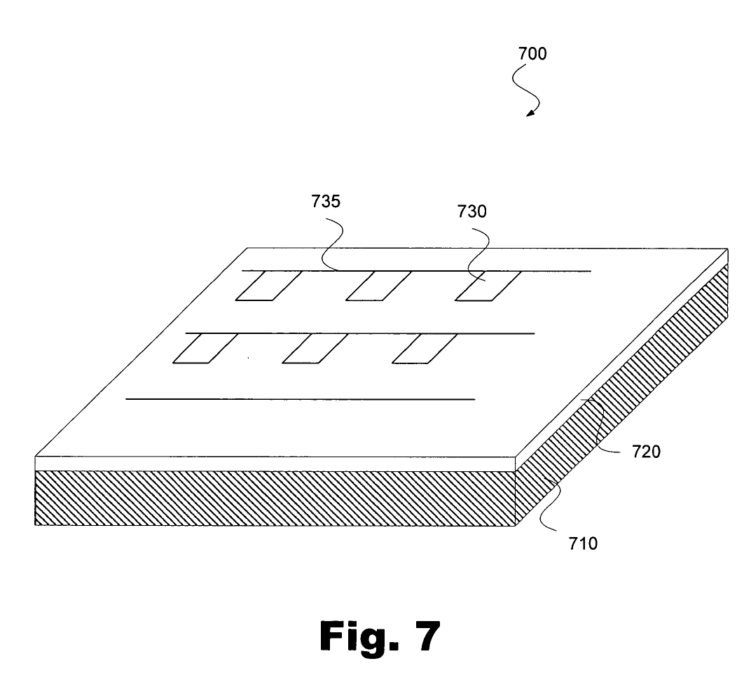

Once the substrate is prepared, an oxide film may be dispensed over the prepared substrate (step 610). According to one exemplary embodiment, the oxide film dispensed on the prepared substrate may include, but is in no way limited to, a zinc oxide or a zinc tin oxide. FIG. 7 illustrates the formation of an active matrix backplane (700) including an exemplary substrate (710) having an oxide film (720) such as zinc oxide or zinc tin oxide formed thereon. As mentioned previously, the oxide film (720) may be formed via any number of appropriate deposition methods including, but in no way limited to, vacuum deposition processes including, but in no way limited to, RF (radio frequency) sputtering, DC sputtering, DC-pulsed sputtering, reactive sputtering, thermal evaporation, electron-beam evaporation, chemical vapor deposition (CVD), or atomic layer deposition (ALD). Additionally, the oxide film (720) may be formed via spin coating processes, curtain coating processes, inkjet coating processes, and the like. Once initially deposited, the oxide film (720) exhibits electrically insulating properties.

After the non-patterned oxide layer has been deposited (step 610; FIG. 6), the oxide film may be locally annealed to form a number of conductive elements such as a gate electrode and a control line (step 620; FIG. 6). As illustrated in FIG. 7, multiple control lines (735) and gate electrodes (730) may be selectively formed directly in the oxide film (720). As mentioned previously, the conductivity of the non-patterned oxide layer (720) may be selectively modified by the application of laser pulses.

While the present exemplary method is described as forming the multiple control lines (735) and the gate electrodes (730) via application of laser pulses, the present method may include control lines and gate electrodes formed by any number of known formation methods including, but in no way limited to, photolithography, imprint lithography, laser ablation, microcontact printing, inkjet printing, blanket deposition, and the like.

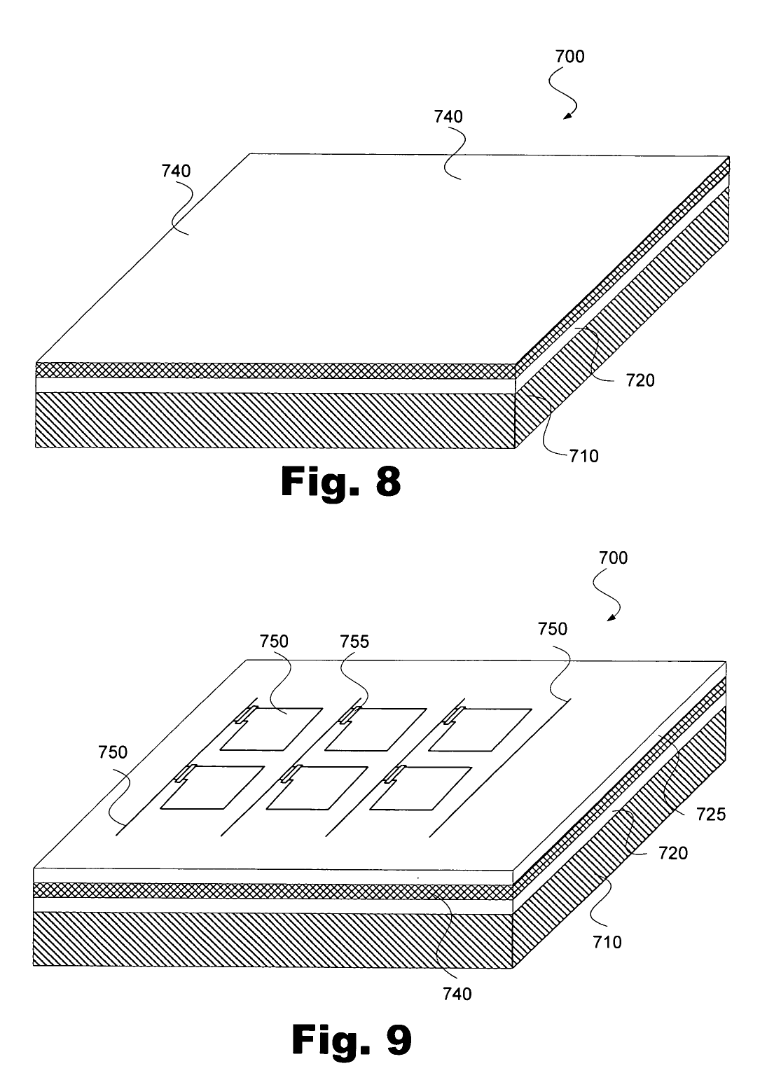

Continuing with the exemplary method of FIG. 6, once the gate electrodes (730; FIG. 7) and control lines (735; FIG. 7) have been formed, a dielectric (740) may be deposited over the formed conductive areas (step 630), as illustrated in FIG. 8. According to one exemplary embodiment, the dielectric (740) may be deposited over the formed conductive areas (735, 730; FIG. 7) of the oxide layer (720) by any number of material deposition apparatuses including, but in no way limited to, an inkjet material dispenser.

With the gate dielectric (740) deposited over the control lines (735; FIG. 7) and gate electrodes (730; FIG. 7), the present exemplary method for forming the backplane continues by depositing a second oxide film (725) over the gate dielectric (step 640), as illustrated in FIG. 9. The second oxide film (725) may then be selectively patterned to form a number of conductive regions (750) and semiconducting regions (755) configured to function as a number of TFT components including, but in no way limited to, a pixel electrode, data lines, a TFT channel, a source electrode, and/or a drain electrode (step 650).

As illustrated in FIG. 9, the second oxide layer (725) may have a number of conductive (750) and semiconductive (755) elements formed therein by the present exemplary selective annealing methods. More specifically, semiconducting material (755), such as to act as a TFT channel layer may be formed on multiple locations of the second oxide layer (725) by selectively annealing the second oxide layer with selective annealing methods such as a laser treatment. According to one exemplary embodiment, the selective annealing of the second oxide film (725) via laser treatment to form a plurality of semiconducting channels includes applying a plurality of laser pulses onto selective areas of the second oxide film, thus improving the semiconducting properties of the film, such as reduced defect (trap) density and increased carrier mobility. In this way, the affected area of the second oxide film (725) is made suitable for use as a TFT channel region. As illustrated in FIG. 9, an array of semiconducting channel layers (755) may be selectively formed in the second oxide film (725).

After the semiconducting material is formed via local annealing, the present exemplary method may also locally anneal areas of the second non-patterned oxide layer (725) adjacent to the semiconducting channel layers (755) to form a number of conductive material elements (750). FIG. 9 illustrates the formation of a number of conductive areas (750) in the second non-patterned oxide layer (725), according to one exemplary embodiment. As illustrated in FIG. 9, a number of conductive areas (750) may be formed in the second non-patterned oxide layer (725) adjacent to the semiconducting channel portions (755) such that they may act as pattern pixel electrodes, source and drain electrodes, and/or active matrix backplane data/control lines. As mentioned previously, the conductivity of the second non-patterned oxide layer (725) may be selectively modified by the application of laser pulses. According to the present exemplary embodiment, the intensity and/or pulse count of the laser application may be increased, when compared to the formation of the above-mentioned semiconductive areas (755), to form the present conductive areas (750). According to one exemplary embodiment, the increased intensity and/or pulse count of the laser application is believed to result in oxygen deficiency in selective portions of the second oxide layer (725), thereby increasing the conductivity of the selective portions until they are sufficiently conductive to serve as pixel electrodes, source and drain electrodes, and/or active matrix backplane data/control lines.

With all of the above-mentioned components formed on the desired substrate, a passivation layer may be deposited, or the substrate may be integrated with the front plate (step 660; FIG. 6), to complete formation of the desired backplane.

As illustrated above, the gate electrode, the source/drain electrode, and/or the channel of a resulting TFT can be formed by the above-mentioned laser processing techniques. However, each of the above components can be independently combined and/or used individually with standard component forming methods.

While the present exemplary system and method are described above in the context of forming a thin-film transistor (TFT), any number of substrates may receive the formation of conductive material, according to the present system and method. According to one exemplary embodiment, a number of substrates were prepared and selectively laser treated to form traces having varying conductivity, as will be described in further detail below.

### EXAMPLES

According to one example, a number of test structures were formed. Initially, a standard thin-film transistor test structure coupon that allows estimation of carrier concentration and mobility, in addition to conductivity was acquired. As implemented, the test structure coupons used included a heavily doped Si wafer, a 1000 Å thermal SiO2 gate dielectric (front), and a Ta/Au gate contact layer (back).

A zinc oxide film was then dispensed on the test structure coupons. Mor specifically, a zinc oxide film was RF sputtered on unheated test structure coupons. The RF sputtering was performed at 100 W RF, 5 mTorr, with an argon/oxygen atmosphere of 90/10% respectively.

Once formed, the zinc oxide layer was laser annealed under Varying conditions. A UV excimer laser having a wavelength of 248 nm was selectively applied to the test structure coupons at fluences between 50-300 mJ/cm2, between 10-10,000 pulse count, and at frequencies between approximately 50 and 200 Hz.

A number of contact electrodes were then formed and the resistivity of the selectively annealed portions of the test structure coupons were tested. The resulting resistivities are illustrated below in Table 1.

TABLE 1

| Fluence | | Frequency | Continuous? | ρ |
|---|---|---|---|---|
| (mJ/cm²) | Shots | (Hz) | (y/n) | (Ω cm) |
| as-deposited | | | | ˜10⁵-10⁶ |
| 50 | 10 | 200 | y | 1 × 10⁵ |
| 50 | 100 | 200 | y | 5 × 10⁵ |
| 50 | 1000 | 200 | y | 4 × 10⁻¹ |
| 50 | 5000 | 200 | y | 3 × 10⁰ |
| 50 | 10000 | 200 | y | 1 × 10⁻¹ |
| 75 | 10 | 200 | y | 3 × 10⁴ |
| 75 | 100 | 200 | y | 1 × 10² |
| 75 | 1000 | 200 | y | 4 × 10⁰ |
| 75 | 5000 | 200 | y | 7 × 10⁻³ |
| 75 | 10000 | 200 | y | 3 × 10⁻¹ |
| 75 | 1000 | 200 | n | 4 × 10⁰ |
| 75 | 5000 | 200 | n | 4 × 10⁻³ |
| 75 | 10000 | 200 | n | 8 × 10⁻³ |
| 75 | 1000 | 50 | y | 2 × 10⁰ |
| 75 | 5000 | 50 | y | 3 × 10⁻² |
| 75 | 10000 | 50 | y | 3 × 10⁻³ |

As illustrated in Table 1, the laser treatment is shown to reduce the zinc oxide film resistivity by as much as approximately 8 orders of magnitude (from approximately 10⁵ to approximately 10⁻³ Ohm cm. According to the exemplary embodiment, the resistivity decrease is a result of a simultaneous increase in carrier concentration and mobility, both of which are inversely proportional to resistivity.

In conclusion, the present exemplary system and method for forming conductive material on a substrate employs simple, low-cost, high performance blanket coating deposition processes while enabling the use of low cost/low temperature, flexible substrates. By replacing traditional global thermal annealing and chemical etch processes with localized and direct laser annealing of the oxide film, a number of advantages are realized. First, overall cost of the substrate production is decreased. For a properly matched laser/oxide pair (i.e., laser with energy such that efficient absorption takes place in the oxide layer; e.g., laser energy slightly above material bandgap), energy should be coupled very efficiently and directly into the oxide film with minimal residual heating of the substrate and/or underlying layers. Second, process complexity is reduced. The present local laser treatment of device and interconnect regions removes the necessity of physically patterning the oxide film so as to obtain electrical isolation between devices. Third, roll-to-roll manufacturing techniques that offer substantially improved throughput, as compared to traditional standard methods employing singulated rigid panels, may be incorporated. Moreover, because the present exemplary system and method eliminate physical patterning, the resulting electrically patterned film is topographically smooth.

The preceding description has been presented only to illustrate and describe exemplary embodiments of the present system and method. It is not intended to be exhaustive or to limit the system and method to any precise form disclosed. Many modifications and variations are possible in light of the above teaching. It is intended that the scope of the system and method be defined by the following claims.

What is claimed is:

1. An apparatus comprising:
a thin-film device having a conductive region formed by laser annealing a first selected portion of a non-conductive blanket coated inorganic material.

2. The apparatus of claim 1, wherein said non-conductive blanket coated inorganic material comprises an oxide material.

3. The apparatus of claim 2, wherein said oxide material comprises one of a zinc oxide and a zinc tin oxide.

4. The apparatus of claim 2, wherein said oxide material comprises zinc tin oxide, with a zinc:tin atomic ratio between approximately 1:2 and approximately 1:0.

5. The apparatus of claim 2, wherein said blanket coated oxide material comprises a material that is substantially insulating in regions outside said laser annealed selected portions.

6. The apparatus of claim 5, wherein said substantially insulating regions of said blanket coated oxide material substantially hinder lateral current flow through said substantially insulating regions of said blanket coated oxide material.

7. The apparatus of claim 1, further comprising a semiconducting region formed by laser annealing a second selected portion of said non-conductive blanket coated inorganic material.

8. The apparatus of claim 7, wherein said laser annealing said second selected portion of said non-conductive blanket coated inorganic material comprises applying a laser beam on said second selected portion of said non-conductive blanket coated inorganic material.

9. The apparatus of claim 8, wherein said laser annealing said first selected portion of said non-conductive blanket coated inorganic material to form said conductive region comprises applying a laser beam on said first selected portion of said non-conductive blanket coated inorganic material at an increased intensity or pulse count than used on said second selected portion of said blanket coated material.

10. The apparatus of claim 1, wherein said laser annealed conductive region comprises a source and a drain electrode portion of a thin-film transistor.

11. An apparatus comprising:
a thin-film device;
wherein said thin-film device includes a conductive region formed by laser annealing a first selected portion of a non-conductive blanket coated inorganic material and a semiconducting region formed by laser annealing a second selected portion of said non-conductive blanket coated inorganic material.

12. The apparatus of claim 11, wherein said non-conductive blanket coated inorganic material comprises an oxide material.

13. The apparatus of claim 11, wherein said conductive region exhibits a resistivity between approximately 10 and 10⁻⁴ Ohm cm.

14. The apparatus of claim 11, wherein said conductive region comprises one of a source electrode a drain electrode, a gate electrode, or a control line.

15. The apparatus of claim 11, wherein said semiconducting region comprises a channel.

16. The apparatus of claim 15, wherein said blanket coated oxide material further comprises a non-laser annealed region;
wherein said non-laser annealed region has properties such that lateral current flow through said non-laser annealed region is substantially precluded.

17. A system for forming a conductive material comprising:
a blanket coated oxide material; and
a laser configured to selectively apply laser beams to selective portions of said blanket coated oxide material;
said laser beams being configured to anneal said selective regions of said blanket coated oxide material to form said conductive material.

18. The system of claim 17, wherein said blanket coated oxide material comprises one of a zinc oxide and a zinc tin oxide.

19. The system of claim 18, wherein said laser comprises a UV excimer laser.

20. A method of making a conductive material comprising selectively treating a portion of a non-conductive inorganic material with one of a laser, a high density infrared plasma arc light, an electron beam emitter, or an ion beam emitter to form a conductive region in said portion.

21. The method of claim 20, wherein said selectively treating an oxide material further comprises exposing said oxide material to a laser beam having energy slightly above a optical bandgap of said oxide material.

22. The method of claim 20, wherein said selectively treating an oxide material comprises selectively exposing said oxide material to at least one laser beam.

23. The method of claim 20, further comprising selectively exposing a first portion of said non-conductive inorganic material to a first laser beam; and
further exposing said first portion of said blanket coated oxide material to a second laser beam.

24. A method comprising:
forming an un-patterned non-conductive inorganic material layer; and
selectively annealing a first portion and a second portion of said un-patterned non-conductive inorganic material layer to form a plurality of conductive regions;
wherein said selective annealing includes selectively treating a portion of said un-patterned non-conductive inorganic material with one of a laser, a high density infrared plasma arc light, an electron beam emitter, or an ion beam emitter.

25. The method of claim 24, wherein said un-patterned material layer comprises an un-patterned oxide layer.

26. The method of claim 24, further comprising selectively annealing a third portion of said un-patterned non-conductive inorganic material layer to form a semiconducting active region.

27. The method of claim 26, wherein said third portion of said un-patterned material layer is disposed between said first portion and said second portion of said material layer such that said first portion is operable to function as a source electrode, said second portion is operable to function as a drain electrode, and said third portion is operable to function as a channel region.

28. The method of claim 24, wherein said first portion of said un-patterned oxide layer and said second portion of said un-patterned oxide layer receive laser pulses from different lasers.

29. The method of claim 24, wherein forming said un-patterned oxide material comprises vacuum depositing said oxide material.

30. The method of claim 29, wherein vacuum depositing the oxide material comprises sputtering said oxide material.

31. A system comprising:
a semiconductor device including a plurality of thin-film transistors;
wherein each of said thin-film transistors includes at least a first and a second conductive region formed by selectively annealing a first and a second selective portion of a non-conductive blanket coated inorganic material.

32. The system of claim 31, wherein said at least first and second selectively annealed conductive regions comprise laser annealed selected portions of said non-conductive blanket coated inorganic material.

33. The system of claim 31, wherein each of said plurality of thin-film transistors further comprises a gate electrode, a source electrode, and a drain electrode.

34. The system of claim 33, wherein:
said first conductive region is operable to function as a source electrode; and
said second conductive region is operable to function as a drain electrode.

35. The system of claim 33, wherein said first conductive region is operable to function as a circuit interconnect.

36. The system of claim 31, wherein each of said plurality of thin-film transistors further comprises a semiconducting region formed by laser annealing a third selective portion of said non-conductive blanket coated inorganic material;
said semiconducting region being configured to function as a channel.

37. The system of claim 31, wherein said non-conductive blanket coated inorganic material further comprises a non-selectively annealed region.

38. The system of claim 37, wherein said non-selectively annealed region has properties such that lateral current flow through said non-selectively annealed region is substantially precluded.

39. The system of claim 31, wherein said semiconductor device comprises an active matrix display.
